(19) United States
(12) Patent Application Publication
(10) Pub. No.: US 2017/0069747 A1
(43) Pub. Date: Mar. 9, 2017

(54) SEMICONDUCTOR DEVICE

(71) Applicant: KABUSHIKI KAISHA TOSHIBA, Tokyo (JP)

(72) Inventors: Yasunobu SAITO, Nomi Ishikawa (JP); Toshiyuki NAKA, Nonoichi Ishikawa (JP); Nobuyuki SATO, Nonoichi Ishikawa (JP)

(21) Appl. No.: 15/062,206

(22) Filed: Mar. 7, 2016

(30) Foreign Application Priority Data
Sep. 3, 2015 (JP) 2015-173428

(51) Int. Cl. H01L 29/778; H01L 29/66; H01L 29/40; H01L 29/423; H01L 29/20; H01L 29/205

(52) U.S. Cl. CPC H01L 29/7787; H01L 29/2003; H01L 29/205; H01L 29/402; H01L 29/4236; H01L 29/66462

(57) ABSTRACT

A semiconductor device capable of suppressing current collapse is provided. The semiconductor device includes a substrate, a nitride semiconductor layer on the substrate, and including a first region and a second region having a thickness greater than that of the first region, a source electrode on the first region, a drain electrode on the second region, and a gate electrode on the first region between the source electrode and the drain electrode.

### CROSS-REFERENCE TO RELATED APPLICATION

This application is based upon and claims the benefit of priority from Japanese Patent Application No. 2015-173428, filed Sep. 3, 2015, the entire contents of which are incorporated herein by reference.

### FIELD

Embodiments of the present invention relate to a semiconductor device.

### BACKGROUND

A nitride semiconductor transistor has high electric breakdown strength. However, when high voltage is applied, ON-resistance of the nitride semiconductor transistor increases, and a phenomenon called current collapse by which drain current is reduced becomes problematic.

In general, current collapse reduces the performance of the transistor. Therefore, in order to realize a high-performance transistor, suppression of current collapse is desired.

### DESCRIPTION OF THE DRAWINGS

FIG. 1 is a schematic cross-sectional view of a semiconductor device of a first embodiment.

FIGS. 2-6 are each a schematic cross-sectional view illustrating a step in a first example of a method of manufacturing the semiconductor device of the first embodiment.

FIGS. 7-8 are each a schematic cross-sectional view of the semiconductor device illustrating a step in a second example of the method of manufacturing the semiconductor device of the first embodiment.

FIGS. 9A and 9B are diagrams illustrating the operation of the semiconductor device of a comparative example.

FIGS. 10A and 10B are diagrams illustrating the operation of the semiconductor device of the first embodiment.

FIG. 11 is a schematic cross-sectional view of a semiconductor device of a second embodiment.

FIG. 12 is a schematic cross-sectional view of a semiconductor device of a third embodiment.

FIG. 13 is a schematic cross-sectional view of a semiconductor device of a fourth embodiment.

FIG. 14 is a schematic cross-sectional view of a semiconductor device of a fifth embodiment.

FIG. 15 is a schematic cross-sectional view of a semiconductor device of a sixth embodiment.

FIG. 16 is a schematic cross-sectional view of a semiconductor device of a seventh embodiment. and

FIG. 17 is a schematic cross-sectional view of a semiconductor device of an eighth embodiment.

### DETAILED DESCRIPTION

Embodiment provide a semiconductor device capable of suppressing current collapse.

In general, according to one embodiment, a semiconductor device includes a substrate, a nitride semiconductor layer on the substrate, and including a first region and a second region having a thickness greater than that of the first region, a source electrode on the first region, a drain electrode on the second region, and a gate electrode on the first region between the source electrode and the drain electrode.

Embodiments of the present invention will be described below using the accompanying drawings.

In this specification, the same reference numerals may be assigned to the same or similar element to avoid redundant description.

The term “nitride (GaN-based) semiconductor” used herein means a semiconductor including GaN (gallium nitride), AlN (aluminum nitride), InN (indium nitride) or their intermediate compositions.

The term “undoped” used herein means that impurity concentration is 1×10¹⁵ cm⁻³ or less.

In order to represent the positional relationship between components and the like herein, the upward direction in the drawing is described as “upper”, and the downward direction in the drawing as “lower”. The concept of “upper” and “lower” herein is not necessarily defined with respect to the direction of the gravity.

### First Embodiment

A semiconductor device according to the present embodiment includes: a substrate; a first nitride semiconductor layer provided on the substrate, and including a first region and a second region having a thickness greater than that of the first region; a source electrode provided on the first region; a drain electrode provided on the second region; and a gate electrode provided on the first region between the source electrode and the drain electrode.

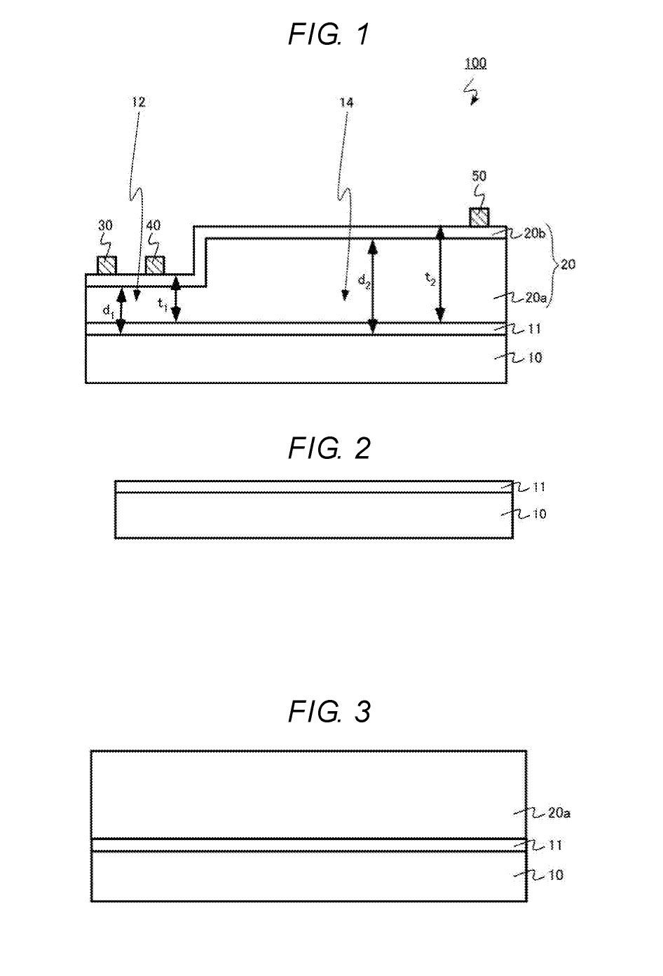

FIG. 1 is a schematic cross-sectional view of a semiconductor device of the embodiment. The semiconductor device of the embodiment is an HEMT (High Electron Mobility Transistor) using a GaN-based semiconductor.

A semiconductor device 100 includes: a substrate 10 including p-type impurity or n-type impurity; a GaN-based semiconductor layer (first nitride semiconductor layer) 20 provided on the substrate 10, and including a first region 12 and a second region 14 having a thickness greater than that of the first region; a source electrode 30 provided on the first region 12; a drain electrode 50 provided on the second region 14; and a gate electrode 40 provided on the first region 12 between the source electrode 30 and the drain electrode 50.

As the substrate 10, a substrate having a low resistance value is preferably used. For example, a semiconductor substrate including p-type impurity or n-type impurity and having a low resistance value is preferably used as a substrate of the embodiment. Specifically, a silicon (Si) substrate or a silicon carbide (SiC) substrate is preferably used. Here, a p-type impurity used in the Si substrate includes, for example, boron (B) or aluminum (Al), and an n-type impurity used in the Si substrate includes, for example, phosphorus (P) or arsenic (As). Further, a p-type impurity used in the SiC substrate includes, for example, B or Al, and an n-type impurity used in the SiC substrate includes, for example, nitrogen (N). In order to achieve a favorable back side field plate effect described later, the resistance value of the substrate 10 is preferably 1 mΩcm or less, for example.

It is preferred that the semiconductor device 100 further includes a GaN-based semiconductor buffer layer (second nitride semiconductor layer) 11 between the substrate 10 and the GaN-based semiconductor layer 20 in order to achieve a high-quality GaN-based semiconductor layer 20 and improve the performance of the semiconductor device. The buffer layer 11 has a function of mitigating the effect of lattice mismatch between the substrate 10 and the GaN-based semiconductor layer 20. The buffer layer 11 has a multi-layer structure made of, for example, aluminum gallium nitride (Al_{W}G_{a1-W}N (0<W<1)).

The GaN-based semiconductor layer 20 includes a first semiconductor layer 20a, and a second semiconductor layer 20b provided on the first semiconductor layer 20a and having a larger band gap than that of the first semiconductor layer 20a, which results in a transistor having an HEMT structure exhibiting high electron mobility. The first semiconductor layer 20a is an undoped Al_{X}Ga_{1-X}N (0≦X<1) , for example. More specifically, x=0 and it is thus an undoped GaN, for example. The thickness of the first semiconductor layer 20a is, for example, 0.5 μm or more and 3 μm or less. The second semiconductor layer 20b is an undoped Al_{Y}Ga_{1-Y}N (0<Y≦1, X<Y), for example. More specifically, it is an undoped Al_{0.2}Ga_{0.8}N, for example. The thickness of the second semiconductor layer 20b is, for example, 15 nm or more and 50 nm or less.

A heterojunction interface is formed between the first semiconductor layer 20a and the second semiconductor layer 20b. During the ON operation of the semiconductor device 100, two-dimensional electron gas (2DEG) is formed at the heterojunction interface, and the gas serves as a carrier.

A thickness t₂ of the second region 14 is preferably larger than a thickness t₁ of the first region 12. More specifically, it is preferred that the difference between the thickness t₂ of the second region 14 and the thickness t₁ of the first region 12 is 100 nm or more and 1 μm or less, that is, 100 nm≦t₂−t₁≦1 μm. When the difference between t₂ and t₁ is less than 100 nm, since the difference between the thickness t₁ of the first region 12 and the thickness t₂ of the second region 14 is too small, it is difficult to sufficiently lower the electric field near the gate electrode 40 described later. Further, when the difference between t₂ and t₁ is more than 1 μm, since the difference between the thickness t₁ of the first region 12 and the thickness t₂ of the second region 14 is too large, it is difficult to form a high-quality second semiconductor layer 20b on the first semiconductor layer 20a.

Similarly, it is preferred that a distance d₂ between the substrate 10 and the second semiconductor layer 20b in the second region 14 is longer than a distance d₁ between the substrate 10 and the second semiconductor layer 20b in the first region 12. More specifically, it is preferred that the difference between the distance d₂ between the substrate 10 and the second semiconductor layer 20b in the second region 14 and the distance d₁ between the substrate 10 and the second semiconductor layer 20b in the first region 12 is 100 nm or more and 1 μm or less, that is, 100 nm≦d₂−d₁≦1 μm.

The source electrode 30, the gate electrode 40 and the drain electrode 50 are, for example, metal electrodes. Here, a metal electrode has a stacked structure of titanium (Ti) and aluminum (Al), or a stacked structure of nickel (Ni) and gold (Au), for example. Preferably, an ohmic junction is formed between each of the source electrode 30, the gate electrode 40 and the drain electrode 50, and the GaN-based semiconductor layer 20 or the second semiconductor layer 20b. It is preferred that the distance between the source electrode 30 and the drain electrode 50 is, for example, 5 μm or more and 30 μm or less.

It is preferred that the source electrode 30 or the gate electrode 50 and the substrate 10 are electrically connected to each other in order to obtain a back side field plate effect. For example, a conductive paste is applied on the substrate 10, and the semiconductor device 100 is mounted on a metal bed. Then, the metal bed and the source electrode 30 or the gate electrodes 50 are wire bonded together to electrically connect the source electrode 30 or the gate electrode 50 with the substrate 10.

Next, a first example of a method of manufacturing the semiconductor device 100 of the embodiment will be described. FIGS. 2 to 6 are schematic cross-sectional views of the semiconductor device 100 during manufacture in the first example of the method of manufacturing the semiconductor device of the embodiment.

The method of manufacturing the semiconductor device of the embodiment includes: forming the buffer layer 11 on the substrate 10 including p-type impurity or n-type impurity by an epitaxial growth method, forming the first semiconductor layer 20a on the buffer layer 11, removing a portion of the first semiconductor layer 20a in the first region 12, forming the second semiconductor layer 20b on the first semiconductor layer 20a by the epitaxial growth method, and forming the source electrode 30 and the gate electrode 40 on the first region 12 and the drain electrode 50 on the second region 14.

First, the buffer layer 11 is formed on the substrate 10 by the epitaxial growth method, for example (FIG. 2).

Next, the first semiconductor layer 20a is formed on the buffer layer 11 by the epitaxial growth method, for example (FIG. 3).

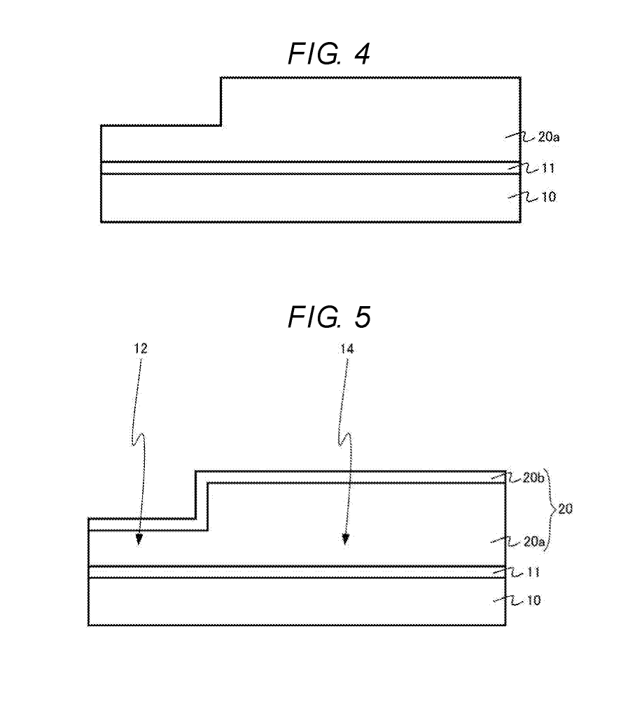

Next, a portion of the first semiconductor layer 20a is removed by etching, for example (FIG. 4).

Next, the second semiconductor layer 20b is formed on the first semiconductor layer 20a by the epitaxial growth method, for example (FIG. 5). In FIG. 4, a region in which a portion of the first semiconductor layer 20a is removed makes up the first region 12, and a region in which no portion of the first semiconductor layer 20a is removed makes up the second region 14.

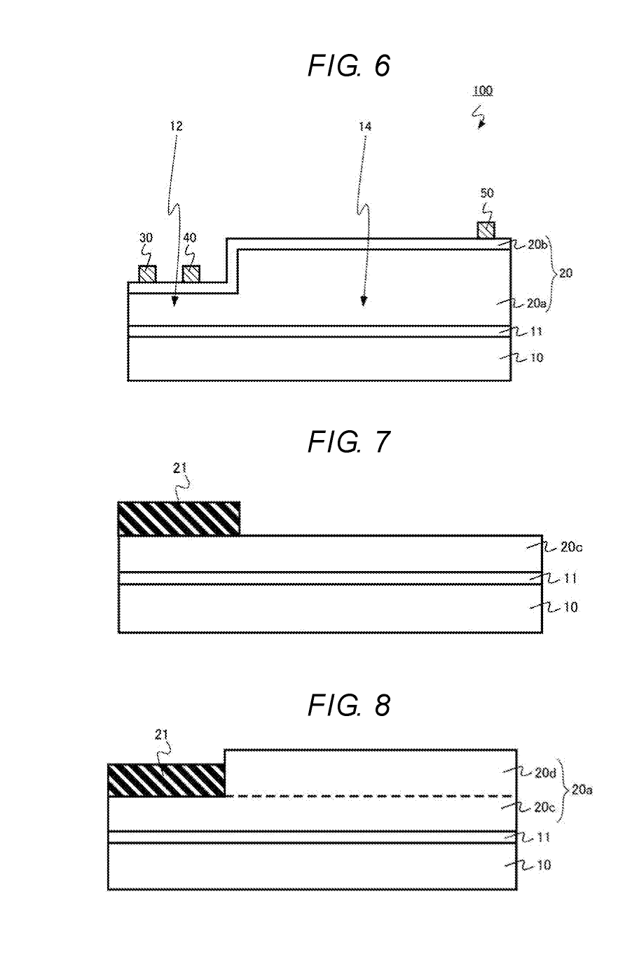

Next, the source electrode 30 having a stacked structure (Ti/Al) of titanium (Ti) and aluminum (Al), for example, and the gate electrode 40 having a stacked structure (Ni/Au) of nickel (Ni) and gold (Au) are formed on the first region 12 by a lift-off method, for example. Further, the drain electrode 50 is formed on the second region 14 (FIG. 6). Thus, the semiconductor device 100 shown in FIG. 1 is manufactured.

Next, a second example of a method of manufacturing the semiconductor device 100 of the embodiment will be described. FIGS. 7 and 8 are schematic cross-sectional views of the semiconductor device 100 in the middle of manufacture in the second example of the method of manufacturing the semiconductor device of the embodiment.

The manufacturing method up to the formation of the buffer layer 11 is the same as that in the first example described above.

Next, a semiconductor layer 20c is formed on the buffer layer 11 by the epitaxial growth method, for example. Next, a mask material 21 of an insulating film is formed on a portion of the surface of the semiconductor layer 20c (FIG. 7).

Next, a semiconductor layer 20d selectively having the same composition as that of the semiconductor layer 20c is formed on the exposed surface of the semiconductor layer 20c by the epitaxial growth method, for example (FIG. 8). Then, the mask material 21 is removed by wet etching, for example.

The first semiconductor layer 20a includes the semiconductor layer 20c and the semiconductor layer 20d. The subsequent manufacturing method is the same as that in the first example. Since a GaN-based semiconductor may be vulnerable to damage by etching and the like, the first semiconductor layer 20a is formed by multiple steps. Thus, a semiconductor device less vulnerable to damage by etching and the like can be provided in the second example.

Next, the operation and effects of the semiconductor device 100 of the embodiment will be described.

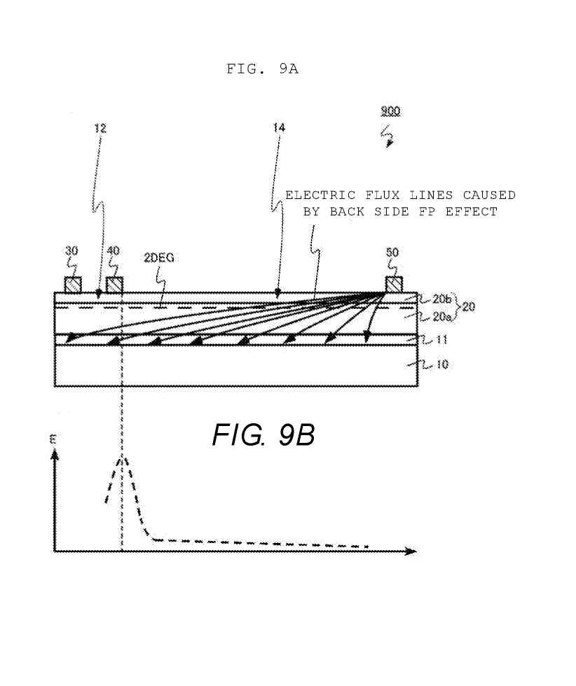

FIGS . 9A and 9B are diagrams illustrating the operation of a semiconductor device 900 of a comparative embodiment. FIG. 9A is a schematic cross-sectional view of the semiconductor device 900 of the comparative embodiment, and FIG. 9B is a schematic view illustrating a lateral electric field E in the semiconductor device 900 shown in FIG. 9A.

When a high electric field is applied to the HEMT made of a nitride semiconductor, a phenomenon called current collapse in which current is reduced may be observed. Since the distance between the gate electrode and the drain electrode is shorter than the distance between the source electrode and the drain electrode when an electric field is applied to the HEMT, many electric flux lines are apt to enter into the gate electrode from the drain electrode. Therefore, a strong electric field is applied in the vicinity of the gate electrode, and particularly, current collapse is apt to occur in the vicinity of the gate electrode. For example, the current collapse is caused by the high electric field when an electron is accelerated, and trapped by a defect and the interface state in the epitaxial layer (i.e., the electronic energy level formed in the interface of semiconductor layer or the interface between the semiconductor layer and the insulating layer), and two-dimensional electron gas density is reduced.

In order to mitigate the electric field inside the HEMT, it is preferred that the substrate 10 and the source electrode 30 or the gate electrode 40 are electrically connected to each other, so that one end of the electric flux line is provided on the substrate 10 side, that is, it is preferred to use a so-called back side field plate (FP) effect. Multiple arrows in FIG. 9A illustrate an example of electric flux lines caused by the back side field plate effect.

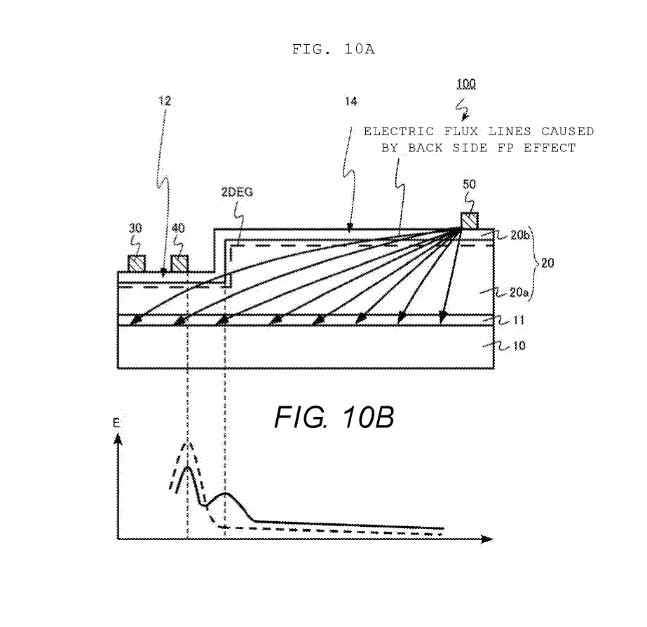

FIGS. 10A and 10B are diagrams illustrating the operation of the semiconductor device 100 of the embodiment. FIG. 10A is a schematic cross-sectional view of the semiconductor device 100 of the embodiment, and FIG. 10B is a schematic view showing a lateral electric field E in the semiconductor device 100 of the embodiment shown in FIG. 10A. In this case, more electric flux lines caused by the back side field plate effect pass through the boundary between the first region 12 and the second region 14. Therefore, as shown by the solid line in FIG. 10B, the electric field at the boundary between the first region 12 and the second region 14 becomes high. On the other hand, when the voltage applied to the semiconductor device 100 is constant, as the electric field at the boundary between the first region 12 and the second region 14 is increased, the electric field in the vicinity of the gate electrode 40 becomes low. As a result, the occurrence of current collapse is suppressed.

Note that the same effect can be expected when plurality of field plate electrodes described later is used. However, it is more difficult to provide a plurality of field plate electrodes in terms of the process. From this viewpoint, the semiconductor device 100 of the embodiment is preferable because it can be easily manufactured.

As described above, according to the semiconductor device 100 of the embodiment, it is possible to provide a semiconductor device capable of suppressing current collapse.

### Second Embodiment

A semiconductor device of this embodiment is different from the semiconductor device of the first embodiment in that a GaN-based semiconductor layer further includes a third region provided between the first region and the second region, and a thickness of the third region is larger than that of the first region and less than that of the second region. Here, the description overlapping with the semiconductor device of the first embodiment will be omitted.

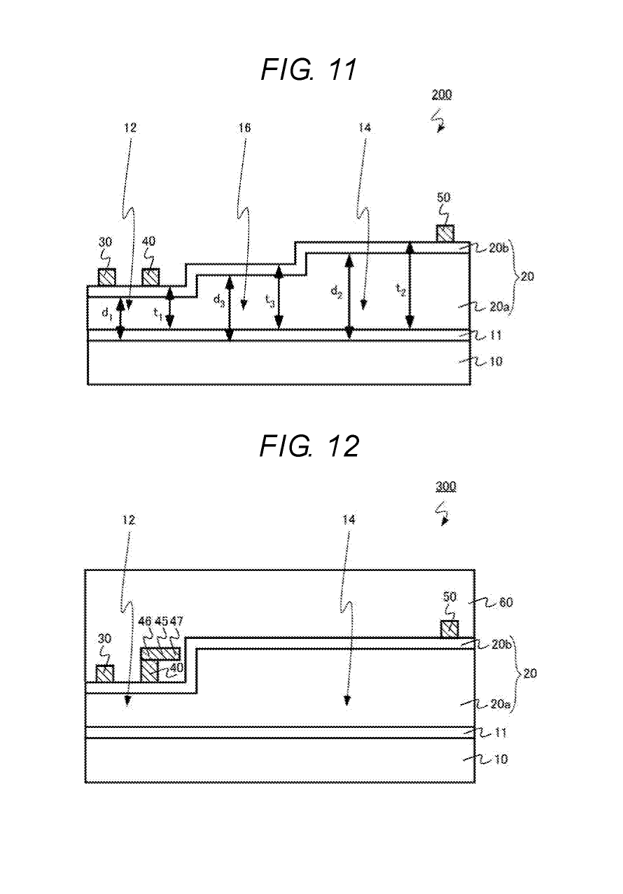

FIG. 11 is a schematic cross-sectional view of a semiconductor device 200 of the embodiment.

A thickness t₃ of a third region 16 is larger than the thickness t₁ of the first region 12 and less than the thickness t₂ of the second region 14. Further, it is preferred that a distance d₃ between the substrate 10 and the second semiconductor layer 20b in the third region 16 is larger than the distance d₁ between the substrate 10 and the second semiconductor layer 20b in the first region 12, and less than the distance d₂ between the substrate 10 and the second semiconductor layer 20b in the second region 14.

According to the semiconductor device 200 of the embodiment, a portion having a higher electric field is provided in the vicinity of the boundary between the first region 12 and the third region 16 and in the vicinity of the boundary between the third region 16 and the second region 14. Therefore, the strength of the electric field is further reduced. Thus, it is possible to provide a semiconductor device capable of further suppressing current collapse, as compared with the first embodiment.

### Third Embodiment

A semiconductor device of the embodiment is different from the semiconductor device of the first embodiment in that a gate field plate electrode 45 having an end electrically connected to the gate electrode is further provided. Here, the description overlapping with the first and second embodiments will be omitted.

FIG. 12 is a schematic cross-sectional view of a semiconductor device 300 of the embodiment.

The semiconductor device of the embodiment includes a gate field plate electrode. One end 46 of the gate field plate electrode is electrically connected to the gate electrode 40. The other end 47 of the gate field plate electrode is provided between the gate electrode 40 and the drain electrode 50. Since the gate field plate electrode is provided, a portion having a higher electric field can be further provided on a channel in the vicinity directly below the other end 47 of the gate field plate electrode. Therefore, current collapse is further suppressed.

The other end 47 of the gate field plate electrode may be provided in the first region 12, the second region 14, or the third region of the second embodiment. Depending on application of the semiconductor device 100 such as a voltage applied to the semiconductor device 100, the position of the end of the gate field plate electrode may be appropriately changed.

Further, although one gate field plate electrode is provided on the semiconductor device 300 of the embodiment, for example, two or more gate field plate electrodes may be appropriately provided.

Note that an insulating film 60 is provided around the source electrode 30, the gate electrode 40, the gate field plate electrode 45 and the drain electrode 50 on the first semiconductor layer. The insulating film 60 is formed using, for example, a silicon oxide film or a silicon nitride film.

As described above, in the semiconductor device 300 of the embodiment, the gate field plate electrode is provided. Thus, it is possible to provide a semiconductor device capable of further suppressing current collapse as compared with the first embodiment.

### Fourth Embodiment

A semiconductor device of the embodiment is different from the semiconductor device of the first embodiment in that a source field plate electrode having an end electrically connected to the source electrode is further provided. Here, the description overlapping with the first to third embodiments will be omitted.

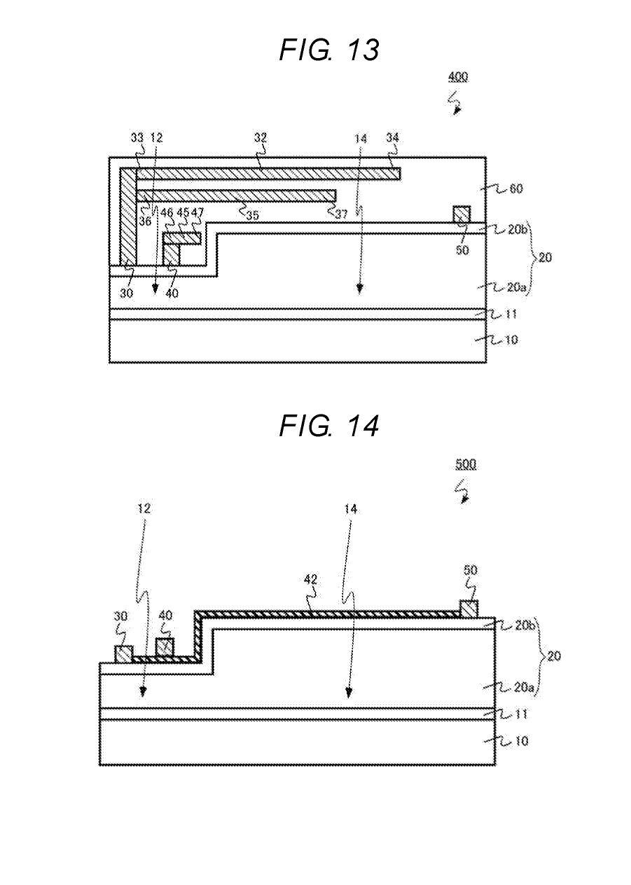

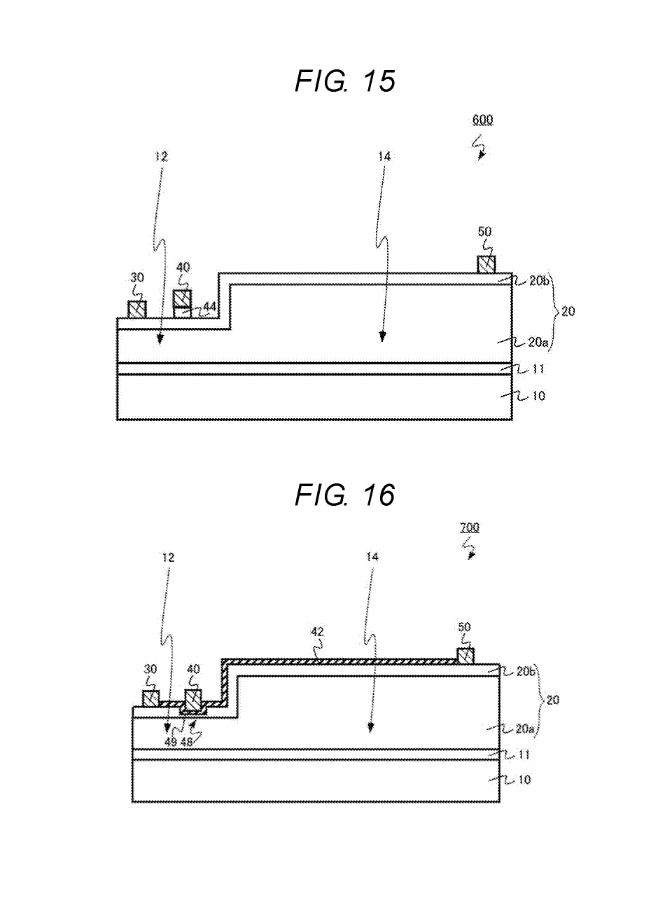

FIG. 13 is a schematic cross-sectional view of a semiconductor device 400 of the embodiment.

The semiconductor device 400 of the embodiment includes a first source field plate electrode 32 and a second source field plate electrode 35. The first source field plate electrode 32 is provided above the second source field plate electrode 35. One end 33 of the first source field plate electrode is electrically connected to the source electrode 30, and the other end 34 of the first source field plate electrode is provided in the second region 14. Further, one end 36 of the second source field plate electrode is electrically connected to the source electrode 30, and the other end 37 of the second source field plate electrode is provided in the second region 14. Thus, a portion having a higher electric field can be further provided on a channel in the vicinity directly below the other end 34 of the first source field plate electrode and a channel in the vicinity directly below the other end 37 of the second source field plate electrode. Therefore, the semiconductor device 400 of the embodiment can further suppress current collapse.

Note that, in the semiconductor device 400 of the embodiment, the other end 34 of the first source field plate electrode and the other end 37 of the second source field plate electrode 37 are provided in the second region 14. However, they may be provided in the first region 12 or in the third region 16 of the second embodiment. Here, in order to properly apply an electric field to a channel, it is preferred that the other end 34 of the first source field plate electrode extend farther from the source electrode 30 than the other end 37 of the second source field plate electrode. Further, in order to properly apply an electric field to a channel, it is preferred that the other end 34 of the first source field plate electrode is provided on a location closer to the upper portion of the drain electrode 50 than the other end 37 of the second source field plate electrode.

As described above, in the semiconductor device 400 of the embodiment, the source field plate electrode is provided. Thus, it is possible to provide a semiconductor device capable of further suppressing current collapse, as compared with the first embodiment.

### Fifth Embodiment

A semiconductor device of the embodiment is different from the semiconductor device of the first embodiment in that a gate insulating film is further provided between the GaN-based semiconductor layer and the gate electrode. Here, the description overlapping with the first to fourth embodiments will be omitted.

FIG. 14 is a schematic cross-sectional view of a semiconductor device 500 of the embodiment.

A gate insulating film 42 preferably includes, for example, a silicon nitride (SiNₓ) film, an aluminum nitride (AlNₓ) film, a silicon oxynitride (SiO_{y}Nₓ) film or an aluminum oxynitride (AlO_{y}) film.

Also in the semiconductor device 500 of the embodiment, it is possible to provide a semiconductor device capable of suppressing current collapse.

### Sixth Embodiment

A semiconductor device of the embodiment is different from the semiconductor device of the first embodiment in that a cap layer (third nitride semiconductor layer) is further provided between the GaN-based semiconductor layer and the gate electrode. Here, the description overlapping with the first to fifth embodiments will be omitted.

FIG. 15 is a schematic cross-sectional view of a semiconductor device 600 of the embodiment.

A cap layer 44 is, for example, a p-type Al_{U}G_{a1-U}N (0≦U<1). More specifically, it is, for example, a p-type GaN. A thickness of the cap layer 44 is, for example, 50 nm or more and 200 nm or less. The semiconductor device 600 of the embodiment is a normally-off semiconductor device.

In the semiconductor device 600 of the embodiment, it is possible to provide a normally-off semiconductor device capable of suppressing current collapse.

### Seventh Embodiment

A semiconductor device 700 of the embodiment is different from the semiconductor device of the first to sixth embodiments in that a distance between the gate electrode and the substrate is shorter than a distance between the source electrode and the substrate. Here, the description overlapping with the first to sixth embodiments will be omitted.

FIG. 16 is a schematic cross-sectional view of a semiconductor device 700 of the embodiment.

In the semiconductor device 700 of the embodiment, the semiconductor layer 20b has a groove (trench or recess) 48 provided thereon. The gate electrode 40 is provided in the groove 48. A groove bottom 49 is provided in the second GaN-based semiconductor layer 20b. Further, the gate insulating film 42 is provided between the gate electrode 40 and the groove bottom 49. Therefore, the distance between the gate electrode 40 and the substrate 10 is shorter than the distance between the source electrode 30 and the substrate 10. The semiconductor device 100 of the embodiment is a normally-off semiconductor device.

In the semiconductor device 100 of the embodiment, it is possible to provide a normally-off semiconductor device capable of suppressing current collapse.

### Eighth Embodiment

A semiconductor device 800 of the embodiment is different from the semiconductor device 700 of the seventh embodiment in that the bottom of the groove is provided in the first semiconductor layer. Here, the description overlapping with the first and seventh embodiments will be omitted.

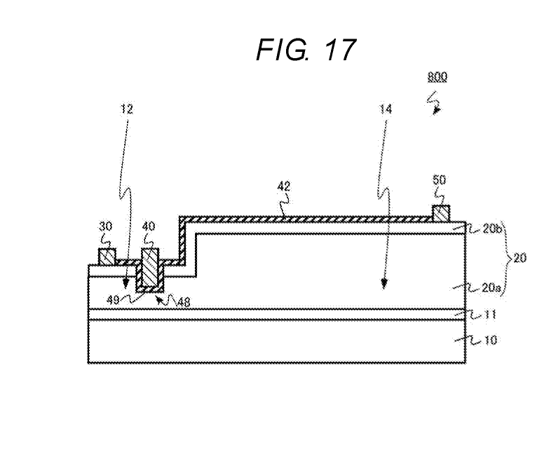

FIG. 17 is a schematic cross-sectional view of the semiconductor device 800 of the embodiment. The groove bottom 49 is provided in the first semiconductor layer 20a. The semiconductor device 800 of the embodiment is a normally-off semiconductor device.

Also in the semiconductor device 800 of the embodiment, it is possible to provide a normally-off semiconductor device capable of suppressing current collapse.

While certain embodiments and examples have been described, these embodiments and examples have been presented byway of example only, and are not intended to limit the scope of the inventions. Indeed, the novel embodiments described herein maybe embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a nitride semiconductor layer on the substrate, and including a first region and a second region having a thickness greater than that of the first region;
a source electrode on the first region;
a drain electrode on the second region; and
a gate electrode on the first region between the source electrode and the drain electrode.

2. The semiconductor device according to claim 1, wherein either the source electrode or the gate electrode is electrically connected to the substrate.

3. The semiconductor device according to claim 1, wherein a resistance value of the substrate is a 1 mΩcm or less.

4. The semiconductor device according to claim 1, wherein a difference between the thickness of the second region and the thickness of the first region is 100 nm or more and 1 μm or less.

5. The semiconductor device according to claim 1, wherein the nitride semiconductor layer includes a first semiconductor layer, and a second semiconductor layer provided on the first semiconductor layer and having a band gap larger than that of the first semiconductor layer.

6. The semiconductor device according to claim 5, wherein a distance between the substrate and the second semiconductor layer in the second region is larger than a distance between the substrate and the second semiconductor layer in the first region.

7. The semiconductor device according to claim 1, further comprising a buffer layer of nitride semiconductor between the substrate and the nitride semiconductor layer.

8. The semiconductor device according to claim 1, wherein the nitride semiconductor layer further includes a third region between the first region and the second region, and a thickness of the third region is larger than the thickness of the first region and less than the thickness of the second region.

9. The semiconductor device according to claim 1, further comprising a gate field plate electrode having a first end in contact with the gate electrode and a second end that extends away from the gate electrode towards the drain electrode.

10. The semiconductor device according to claim 9, further comprising a source field plate electrode having a first end in contact with the source electrode and a second end that extends away from the source electrode towards the drain electrode.

11. The semiconductor device according to claim 1, further comprising a cap layer of p-type nitride semiconductor between the nitride semiconductor layer and the gate electrode.

12. The semiconductor device according to claim 1, further comprising a gate insulating film between the nitride semiconductor layer and the gate electrode.

13. The semiconductor device according to claim 12, wherein a closest distance between the gate electrode and the substrate is less than a closest distance between the source electrode and the substrate.

14. The semiconductor device according to claim 13, wherein the nitride semiconductor layer includes a first semiconductor layer, and a second semiconductor layer provided on the first semiconductor layer and having a band gap larger than that of the first semiconductor layer.

15. The semiconductor device according to claim 14, wherein a bottom of the gate electrode extends inwardly of an upper surface of the second semiconductor layer.

16. The semiconductor device according to claim 14, wherein a bottom of the gate electrode extends inwardly of an upper surface of the first semiconductor layer.

17. A semiconductor device, comprising:
a substrate;
a first nitride semiconductor layer having a first region and a second region having a thickness greater than that of the first region, wherein a difference between the thickness of the second region and the thickness of the first region is 100 nm or more and 1 μm or less;
a second nitride semiconductor layer between the substrate and the first nitride semiconductor layer;
a source electrode on the first region;
a drain electrode on the second region; and
a gate electrode on the first region between the source electrode and the drain electrode,
wherein either the source electrode or the gate electrode is electrically connected to the substrate.

18. The semiconductor device according to claim 17, wherein the first nitride semiconductor layer further includes a third region between the first region and the second region, and a thickness of the third region is larger than the thickness of the first region and less than the thickness of the second region.

19. The semiconductor device according to claim 17, further comprising a cap layer of p-type nitride semiconductor between the first nitride semiconductor layer and the gate electrode.

20. The semiconductor device according to claim 17, further comprising a gate insulating film between the first nitride semiconductor layer and the gate electrode.
